(19) United States
(12) Patent Application Publication
(10) Pub. No.: US 2021/0257815 A1
(43) Pub. Date: Aug. 19, 2021

(54) LASER DIODE CHIP, PACKAGE, TRANSMISSION APPARATUS, RANGING APPARATUS, AND ELECTRONIC DEVICE

(71) Applicant: SZ DJI TECHNOLOGY CO., LTD., Shenzhen (CN)

(72) Inventors: Xiang LIU, Shenzhen (CN); Shuai DONG, Shenzhen (CN); Xiaoping HONG, Shenzhen (CN)

(21) Appl. No.: 17/246,370

(22) Filed: Apr. 30, 2021

Related U.S. Application Data
(63) Continuation of application No. PCT/CN2018/112972, filed on Oct. 31, 2018.

(51) Int. Cl. H01S 5/40; H01S 5/042; G01S 7/481; G01S 17/08

(52) U.S. Cl. CPC H01S 5/4025; G01S 17/08; G01S 7/4815; H01S 5/04256

(57) ABSTRACT

A laser diode chip includes a substrate including a first surface and a second surface, and a laser diode array including at least two laser diodes formed at the substrate. Each of the at least two laser diodes includes a P electrode formed at the first surface of the substrate, an N electrode formed at the second surface of the substrate, and a light emitting region formed between the P electrode and N electrode. Adjacent N electrodes of adjacent laser diodes of the at least two laser diodes are isolated from each other.

### CROSS-REFERENCE TO RELATED APPLICATION

This application is a continuation of International Application No. PCT/CN2018/112972, filed Oct. 31, 2018, the entire content of which is incorporated herein by reference.

### TECHNICAL FIELD

The present disclosure relates to the field of integrated circuits and, more particularly, to a laser diode chip, a laser diode package, a transmission apparatus, a ranging apparatus, and an electronic device.

### BACKGROUND

A lidar is a perception system of the outside world, which can acquire three-dimensional information of the outside world. Its principle is to actively transmit laser pulse signals to the outside, detect reflected echo signals, and determine a distance of an object to be detected according to time difference between transmission and reception. Combined with emission direction information of the laser pulse signals, the three-dimensional depth information of the object to be detected can be reconstructed. How to measure as many azimuths as possible in the field of view within a specific time is a technical difficulty of the lidar. One solution is to use a multi-line light source to detect multiple directions, which can effectively increase the orientation of the detection, thereby obtaining environmental data with higher spatial resolution.

For example, for a scanning lidar, a single-line sensor method is equivalent to drawing on a paper with a pen. Using a multi-line sensor is equivalent to holding multiple pens and drawing on a paper, such that blank areas between strokes (which can be understood as blind areas detected in a certain period) will be smaller. In this process, we expect that sensors of different channels can emit light in a time-sharing manner, such that the total peak radiation power may be reduced to meet laser safety regulations and avoid damage to human eyes. Further, time-sharing light emission can also help to reduce the mutual interference between different channels and improve the performance of the system.

Semiconductor laser diodes have been widely used in lidars due to their ease of mass production and low cost. Since a divergence angle of light radiated by a laser diode is usually large, it is usually needed to use a lens for collimation, which requires fine adjustment of relative positions of the laser diode and the lens. In existing technologies, packaged laser diode chip devices are integrated through mechanical processing. The mechanical processing accuracy of this method is difficult to meet position accuracy required by the lens collimation of the emitted laser, and it is needed to repeat adjustment several times for each channel separately. The complexity and cost of the system are increased. By using a micro/nano machining process to package the laser diodes into multiple lines, deviation of the relative positions between the different channels from the design value can be minimized, which facilitates the simultaneous focusing of different lasers and ensures the accuracy of the detection direction of different channels.

However, the current multi-line packaging methods of laser diodes have different problems. First, packaging the individual unpackaged laser diode chips together to realize multi-line sensors requires a machine to control the relative position of the chips, and precision requirements of the machine are relatively high. Further, when the number of lines is large, the complexity and cost of packaging will increase, and also the difficulty of process control will increase. Second, in the manufacturing process of the laser diode chips, the micro/nano machining process is used to etch the structure on the epitaxial wafer to limit the injection current area or use the lateral refractive index distribution to form an optical waveguide. In the micro-nano machining process, this precision can be controlled to be very high, reaching the sub-micron level, such a multi-line sensor with accurate pitch can be formed when a multi-line laser diode chip is cut directly. However, in the existing technologies, N electrodes of the laser chips are connected together. In the application scenarios of the laser diodes, to ensure the pulse quality, it is often needed to use an N-electrode driving mode, which will cause multi-line lasers to emit light simultaneously. Problems including high output power and easy to cause damage to human eyes will appear. Because of the above problems, its application in the realization of lidars multi-line light sources is limited.

Therefore, to facilitate the large-scale massive production and application of lidars, it is needed to improve the current multi-line laser diode chip.

### SUMMARY

In accordance with the disclosure, there is provided a laser diode chip including a substrate including a first surface and a second surface, and a laser diode array including at least two laser diodes formed at the substrate. Each of the at least two laser diodes includes a P electrode formed at the first surface of the substrate, an N electrode formed at the second surface of the substrate, and a light emitting region formed between the P electrode and N electrode. Adjacent N electrodes of adjacent laser diodes of the at least two laser diodes are isolated from each other.

Also in accordance with the disclosure, there is provided a laser diode package including a base plate including a surface, a cover disposed at the surface of the base plate to form an accommodation space between the cover and the base plate, and a laser diode chip arranged in the accommodation space. The laser diode chip includes a substrate including a first surface and a second surface, and a laser diode array including at least two laser diodes formed at the substrate. Each of the at least two laser diodes includes a P electrode formed at the first surface of the substrate, an N electrode formed at the second surface of the substrate, and a light emitting region formed between the P electrode and N electrode. Adjacent N electrodes of adjacent laser diodes of the at least two laser diodes are isolated from each other.

Also in accordance with the disclosure, there is provided a laser transmission apparatus including a laser diode package and a circuit board. The laser diode package includes a base plate including a surface, a cover disposed at the surface of the base plate to form an accommodation space between the cover and the base plate, and a laser diode chip arranged in the accommodation space. The laser diode chip includes a substrate including a first surface and a second surface, and a laser diode array including at least two laser diodes formed at the substrate. Each of the at least two laser diodes includes a P electrode formed at the first surface of the substrate, an N electrode formed at the second surface of the substrate, and a light emitting region formed between the P electrode and N electrode. Adjacent N electrodes of adjacent laser diodes of the at least two laser diodes are isolated from each other. The base plate is attached to the circuit board and electrically couples the laser diode chip to the circuit board.

Also in accordance with the disclosure, there is provided a ranging apparatus including a laser transmission apparatus, at least two photoelectric converters, and a data processor. The laser transmission apparatus includes a laser diode package and a circuit board. The laser diode package includes a base plate including a surface, a cover disposed at the surface of the base plate to form an accommodation space between the cover and the base plate, and a laser diode chip arranged in the accommodation space. The laser diode chip includes a substrate including a first surface and a second surface, and a laser diode array including at least two laser diodes formed at the substrate. Each of the at least two laser diodes includes a P electrode formed at the first surface of the substrate, an N electrode formed at the second surface of the substrate, and a light emitting region formed between the P electrode and N electrode. Adjacent N electrodes of adjacent laser diodes of the at least two laser diodes are isolated from each other. The base plate is attached to the circuit board and electrically couples the laser diode chip to the circuit board. The at least two photoelectric converters correspond to the at least two laser diodes in a one-to-one correspondence. Each of the at least two photoelectric converters is configured to receive at least part of a light beam emitted by a corresponding one of the at least two laser diodes and reflected by an object, and convert the at least part of the light beam to an electric signal. The data processor is configured to determine a distance between the object and the ranging apparatus based on the electric signal.

### BRIEF DESCRIPTION OF THE DRAWINGS

The above and/or additional aspects and advantages of this disclosure will become obvious and easy to understand from the description of the embodiments in conjunction with the following drawings.

FIG. 1A is a cross-sectional view of a multi-line laser diode chip.

FIG. 1B is a top view of the multi-line laser diode chip in FIG. 1A.

FIG. 2A is cross-sectional view of an exemplary laser diode chip consistent with various embodiments of the present disclosure.

FIG. 2B and FIG. 2C show an exemplary fabrication process of the laser diode chip in FIG. 2A.

FIG. 3 is a cross-sectional view of another exemplary laser diode chip consistent with various embodiments of the present disclosure.

FIG. 4 is a schematic structural diagram of an exemplary ranging apparatus consistent with various embodiments of the present disclosure.

FIG. 5 is a schematic block diagram of another exemplary ranging apparatus consistent with various embodiments of the present disclosure.

FIG. 6 is a schematic structural diagram of another exemplary ranging apparatus consistent with various embodiments of the present disclosure.

### DETAILED DESCRIPTION OF THE EMBODIMENTS

Technical solutions of the present disclosure will be described with reference to the drawings. It will be appreciated that the described embodiments are part rather than all of the embodiments of the present disclosure. Other embodiments conceived by those having ordinary skills in the art on the basis of the described embodiments without inventive efforts should fall within the scope of the present disclosure.

Example embodiments will be described with reference to the accompanying drawings, in which the same numbers refer to the same or similar elements unless otherwise specified.

As used herein, when a first assembly is referred to as “fixed to” a second assembly, it is intended that the first assembly may be directly attached to the second assembly or may be indirectly attached to the second assembly via another assembly. When a first assembly is referred to as “connecting” to a second assembly, it is intended that the first assembly may be directly connected to the second assembly or may be indirectly connected to the second assembly via a third assembly between them. The terms “perpendicular,” “horizontal,” “left,” “right,” and similar expressions used herein are merely intended for description.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure. The term “and/or” used herein includes any suitable combination of one or more related items listed.

When used herein, the singular forms “a,” “an,” and “said/the” are also intended to include plural forms, unless the context clearly indicates otherwise. It should also be understood that the terms “comprise” and/or “include,” when used in this specification, indicate the existence of the described features, integers, steps, operations, elements, and/or components, but do not exclude the existence or addition of one or more other features, integers, steps, operations, elements, components, and/or groups.

In existing technologies, multi-line laser diode chips usually have problems including high output power and easy damage on human eyes, which limit the application of the laser diode chips in the lidar multi-line light source.

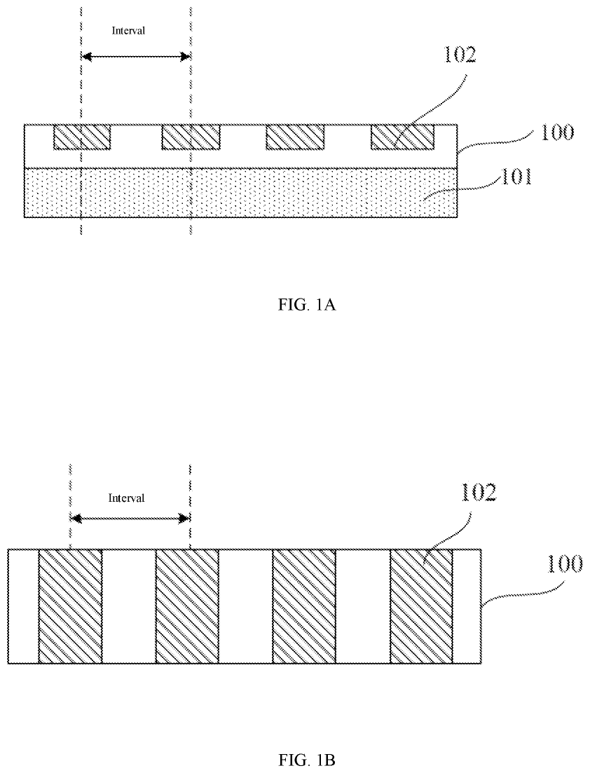

FIG. 1A is a cross-sectional view of a multi-line laser diode chip, and FIG. 1B is a top view of the multi-line laser diode chip in FIG. 1A. As illustrated in FIG. 1A and FIG. 1B, a multi-line laser diode chip usually includes a substrate 100, an N electrode 101 at a side of the substrate 100, and a plurality of P electrodes at another side of the substrate 100. The plurality of P electrodes is arranged at intervals. The N electrode 101 and the plurality of P electrodes 102 are formed by N-type doped/implanted regions and P-type doped/implanted regions respectively. N electrodes of all laser diodes are connected together to use a common N electrode. It can be understood as that the multi-line laser diode is formed at an N-type substrate and the plurality of P electrodes are isolated from each other. A multi-line laser implemented from the laser diode chip in FIG. 1 has following problems.

When a common N electrode driving mode is adopted, all laser diodes will emit light simultaneously. Correspondingly, there will be interference between different lines and the output power is large, which could easily cause damage to human eyes.

When a P electrode driving mode is adopted, light emission in a time sharing manner can be achieved. However, because of the limitation of PMOS parameters, the pulse width generated by the P electrode driving mode is larger than that the pulse width generated by the N electrode driving mode. This causes the pulse energy to increase seriously under the same peak power, which is easy to cause damage to human eyes.

The above problems limit the application of the laser diode chip shown in FIG. 1 in achieving a multi-line light source of a lidar. Other multi-line packaging methods increase complexity and cost of the products. The mass production and application of the lidar are limited. The present disclosure provides a laser diode which can be fabricated using a micro/nano machining process, to at least partially alleviate the above problems. Accuracy of the relative position between the multi-line light sources (that is, the accuracy of the intervals in FIG. 1A and FIG. 1B) may be guaranteed and, independent and rapid drive of each light source (each laser diode) may be achieved.

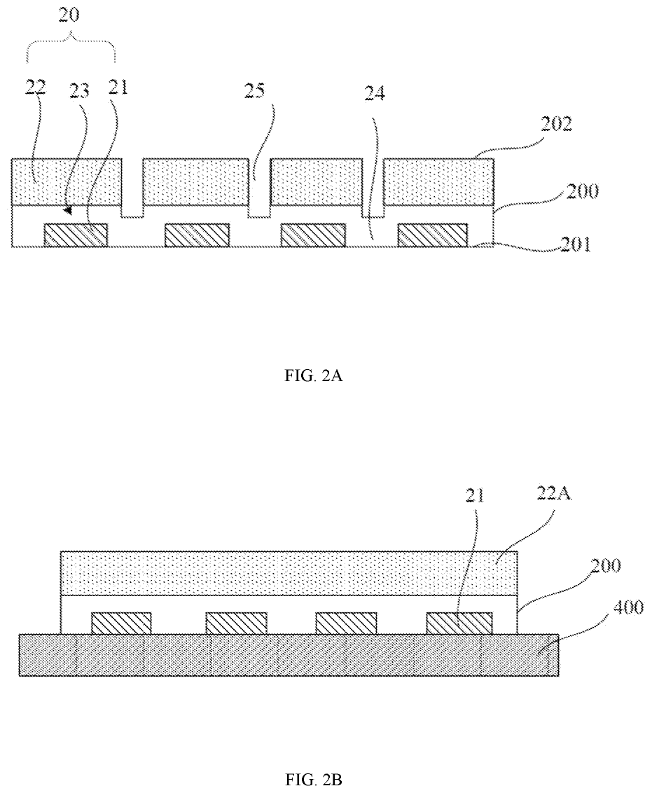

One embodiment of the present disclosure provides a laser diode chip, as shown in FIG. 2A to FIG. 2C.

As shown in FIG. 2A, the laser diode chip includes a substrate 200 having a first surface 201 and a second surface 202, and a laser diode array.

The laser diode array includes at least two laser diodes 20 formed at the substrate 200. Each laser diode 20 of the at least two laser diodes 20 includes a P electrode 21 formed at the first surface 201 of the substrate 200, and an N electrode 22 formed at the second surface 202 of the substrate 200. For each laser diode 20 of the at least two laser diodes 20, a light emitting region 23 is formed between the P electrode 21 and the N electrode 22 of the laser diode 20.

The at least two laser diodes 20 adopt an N electrode driving mode and N electrodes of adjacent laser diodes 20 of the at least two laser diodes 20 are isolated from each other.

In the laser diode chip provided by the present embodiment, the N electrode driving mode may be adopted. Correspondingly, a generated pulse width and then the pulse energy may be small, and it may not induce damage to human eyes. Further, the N electrodes of the adjacent laser diodes may be isolated from each other. Light emission in a time sharing manner may be achieved. Interference between different laser diodes may be reduced, and also a power of radiation peak may be reduced to avoid the damage on human eyes.

In various embodiments, the substrate 200 may be any of suitable semiconductor substrates. For example, in some embodiments, the substrate 200 may be made of at least one of Si, Ge, SiGe, SiC, SiGeC, InAs, GaAs, InP, or other III-V compound semiconductors. The substrate 200 may also include a multilayer structure of semiconductor materials, such as silicon on insulator (SOI), stacked silicon on insulator (SSOI), stacked SiGe on insulator (S—SiGeOI), SiGe on insulator (SiGeOI), or germanium on insulator (GeOI). For description purposes only, the present embodiment where the substrate 200 is made of single-crystalline Si is used as an example to illustrate the present disclosure. Specifically, the substrate 200 may be an intrinsic semiconductor substrate (an undoped semiconductor substrate) or an N-type semiconductor substrate. For example, the N-type semiconductor substrate may be a semiconductor substrate doped with phosphor ions. For example, in one embodiment where the substrate 200 is the N-type semiconductor substrate, the substrate 200 may be a lightly doped N-type semiconductor substrate.

The P electrodes of the at least two laser diodes 20 may be formed at the first surface 201 of the substrate 200. And the adjacent P electrodes 21 may be arranged to be spaced apart from each other. The P electrodes 21 may be formed by doping the first surface 201 of the substrate 200 with a P-type element, such as boron. For example, in one embodiment, the P electrodes 21 are heavily doped with P type ions. When the P electrodes 21 is being formed, a corresponding mask layer may be formed at the first surface 201 of the substrate 200. The shape, position, size of the P electrodes 21, and the spacing between adjacent P electrodes 21 may be defined by the mask layer. As mentioned above, the precision of the spacing can be controlled to be very high in a micro/nano machining process. Then ion implantation or another doping process may be performed using the mask layer as a mask to fabricate the P electrodes 21. Further, in one embodiment, for example, the P electrodes 21 of the adjacent laser diodes 20 may be isolated by intrinsic regions or lightly doped regions 24 at the first surface 201 of the substrate 200. Intrinsic regions or lightly doped regions 24 may refer to regions between the adjacent P electrodes 21 at the substrate 200. These regions may be in the initial state (intrinsic or N-type) of the substrate 200 without further doping, and isolation between adjacent P electrodes 21 can be achieved by using these regions. Of course, in other embodiments, the P electrodes 21 of the adjacent laser diodes 20 may be isolated by isolation structures (such as shallow trench isolation (STI)) or isolation channels at the first surface 201 of the substrate 200.

The N electrodes 22 may be formed at the second surface 202 of the substrate 200, and isolation channels 25 may be provided between the N electrodes 22 of the adjacent laser diodes 20 to realize isolation between the adjacent N electrodes 22. The N electrodes 22 may be formed by doping the second surface 202 of the substrate 200 with an N-type element, such as phosphorus. For example, in one embodiment, the N electrodes 22 may be heavily doped N-type. In one embodiment, the N electrode 22 may be formed by first heavily doping the second surface 202 of the substrate 200 with an N-type element to form a common N electrode shared by the plurality of P electrodes 21, and then forming the isolation channels 25 to divide the common N electrode into the multiple isolated N electrodes 22. Each N electrode 22 may correspond to one P electrode 21, together constituting a corresponding laser diode of the at least two laser diodes. That is, in this embodiment, the N electrode 22 of each laser diode may be formed by cutting the common N electrode formed at the second surface 202 of the substrate 200. Therefore, the size of the N electrodes 22 in the length direction of the substrate 200 (that is, the horizontal direction in FIG. 2A) may be larger than the size of the P electrodes 21 in the length direction of the substrate 200. Each of the isolation channels 25 may include a groove formed by etching or cutting between corresponding adjacent N electrodes 22, and the isolation between the adjacent N electrodes 22 may be realized by the groove. Light emission in a time sharing manner may be achieved accordingly. To achieve isolation between the adjacent N electrodes 22, in some embodiments, the size of the isolation channels 25 in the thickness direction of the substrate 200 (that is, the height/vertical direction in FIG. 2A) may be greater than or equal to the size of the N electrodes in the thickness direction of the substrate 200, and may be smaller than the thickness of the substrate 200. In some embodiments, the grooves may be also filled with insulation materials such as air or silicon dioxide, and the adjacent N electrodes 22 can be isolated better by filling.

In each of the at least two laser diodes, the light emitting region 23 is disposed between the P electrode 21 and the N electrode 22, and may emit laser pulse signals when an excitation signal or a driving signal is applied to the N electrode 22.

In the laser diode chip provided by the present embodiment, the N electrodes of the at least two laser diodes may be isolated from each other. Correspondingly, light emission in a time sharing manner may be achieved when the N electrode driving mode is adopted. The generated pulse width and then the pulse energy may be small, and the damage on human eyes may be avoided.

In the present disclosure, the laser diode chip may be implemented in various manners. One embodiment illustrated in FIG. 2B to FIG. 2C will be used as an example to illustrate the formation of the laser diode chip provided by the above embodiments, and does not limit the scope of the present disclosure.

First, the P electrodes 21 spaced apart from each other and the common N electrode 22A are formed at the substrate 200 using a micro/nano machining process. Then, as shown in FIG. 2B, the formed laser diode chip is placed on a packaging substrate 400. A side of the laser diode chip with the P electrodes 21 faces the package substrate 400. Subsequently, as shown in FIG. 2C, another side of the laser diode chip with the common N electrode 22A is cut or etched by a cutting or etching method, to divide the common N electrode 22A into the N electrodes 22. Each N electrode 22 corresponds to one P electrode 21. The isolation channels 25 formed in the cutting or etching process may isolate the adjacent N electrodes 22, and may be filled with materials in subsequent packaging processes to achieve better isolation.

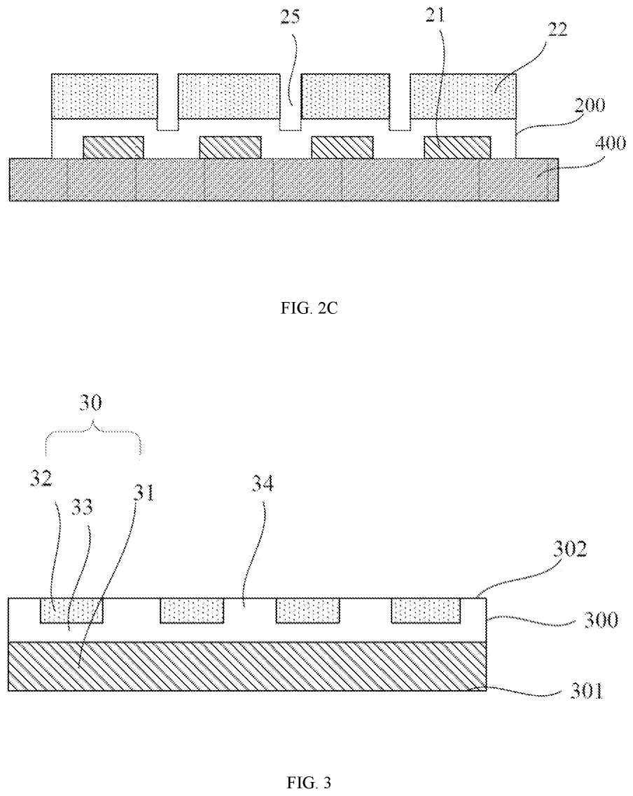

Another embodiment of the present disclosure provides another laser diode chip as shown in FIG. 3.

As showing in FIG. 3, in the present embodiment, the laser diode chip includes a substrate 300 having a first surface 301 and a second surface 302, and a laser diode array including at least two laser diodes 30 formed at the substrate 300.

Each laser diode 30 of the at least two laser diodes 30 is provided with a P electrode 31 formed at the first surface 301 of the substrate 300, an N electrode 32 formed at the second surface 302 of the substrate 300, and a light-emitting region 33 between the P electrode 31 and the N electrode 32 of the laser diode 30.

The at least two laser diodes 30 adopts an N electrode driving mode and N electrodes of any adjacent laser diodes 30 of the at least two laser diodes 30 are isolated from each other.

In the laser diode chip provided by the present embodiment, the N electrode driving mode may be adopted. Correspondingly, a generated pulse width and then the pulse energy may be small, and it may be not easy to induce damage on human eyes. Further, the N electrodes of the adjacent laser diodes may be isolated from each other. Light emission in a time sharing manner may be achieved. Interference between different laser diodes may be reduced, and also a power of radiation peak may be reduced to avoid the damage to human eyes.

In various embodiments, the substrate 300 may be any one of suitable semiconductor substrates. For example, in some embodiments, the substrate 200 may be made of at least one of Si, Ge, SiGe, SiC, SiGeC, InAs, GaAs, InP, or other III-V compound semiconductors. The substrate 200 may also be made of a multilayer structure of these semiconductor materials, silicon on insulator (SOI), stacked silicon on insulator (SSOI), stacked SiGe on insulator (S—SiGeOI), SiGe on insulator (SiGeOI), or germanium on insulator (GeOI). For description purposes only, the present embodiment where the substrate 300 is made of single-crystalline Si is used as an example to illustrate the present disclosure. Specifically, the substrate 300 may be an intrinsic semiconductor substrate (an undoped semiconductor) or a P-type semiconductor substrate. For example, the P-type semiconductor substrate may be a semiconductor substrate doped with phosphor ions. For example, in one embodiment where the substrate 300 is the P-type semiconductor substrate, the substrate 200 may be a lightly doped P-type semiconductor substrate.

For each of the at least two laser diodes, the P electrodes may be formed at the first surface 301 of the substrate 300, and the at least two laser diodes 30 may share one P electrode formed at the first surface 301 of the substrate 300. For example, in one embodiment, the laser diode chip may include four laser diodes, and the four laser diodes may share the one P electrode 31. The P electrode 31 may be formed by doping the first surface 301 of the substrate 300 with a P-type element, such as boron. For example, in one embodiment, the P electrode 31 may be heavily P-type doped, that is, the doping concentration of the P electrode 31 may be larger than the doping concentration of the substrate 300.

The N electrodes 32 of the at least two laser diodes are formed at the second surface 302 of the substrate 300, and are spaced apart from each other. The N electrodes 32 may be formed by doping the second surface 302 of the substrate 300 with an N-type element, such as phosphorus. For example, in one embodiment, the N electrodes 32 may be heavily doped N-type. In one embodiment, when forming the N electrodes 32, a corresponding mask layer may be formed at the second surface 302 of the substrate 300, and the mask layer may be used to define positions, shapes, and sizes of the N electrodes 32, and the space between adjacent N electrodes 32. As described above, the precision of the space can be controlled very high in micro/nano machining process. Then ion implantation or another doping process may be performed using the mask layer as a mask to fabricate the N electrodes 32. Further, in one embodiment, for example, the N electrodes 32 of adjacent laser diodes 30 may be isolated by intrinsic regions or lightly doped regions 34 at the second surface 302 of the substrate 300. Intrinsic regions or lightly doped regions 34 may refer to regions between the adjacent N electrodes 32 at the substrate 300. These regions may be the initial state (intrinsic or P-type) of the substrate 300 without further doping, and isolation between adjacent N electrodes 32 can be achieved by using these regions. Of course, in other embodiments, the N electrodes 32 of adjacent laser diodes 30 may be isolated by isolation structures (such as STI) or isolation channels located at the second surface 302 of the substrate 300.

In each of the at least two laser diodes, the light emitting region 33 is disposed between the P electrode 31 and the N electrode 32, and may emit laser pulse signals when an excitation signal or a driving signal is applied to the N electrode 32.

In the laser diode chip provided by the present disclosure, the N electrodes of the at least two laser diodes may be isolated from each other. Correspondingly, light emission in a time sharing manner may be achieved when the N electrode driving mode is adopted.

The laser diode chip may be implemented by various methods. For example, in one embodiment, the multiple N electrodes may be formed directly on the P-type substrate.

Correspondingly, the micro/nano machining process may be used to guarantee the accuracy of the relative position of the multi-line light sources, and also achieve independent and rapid driving of each light source. Further, a ranging performance and noise characteristics of the lidar may be optimized and the damage on the human eyes may be guaranteed to be avoided.

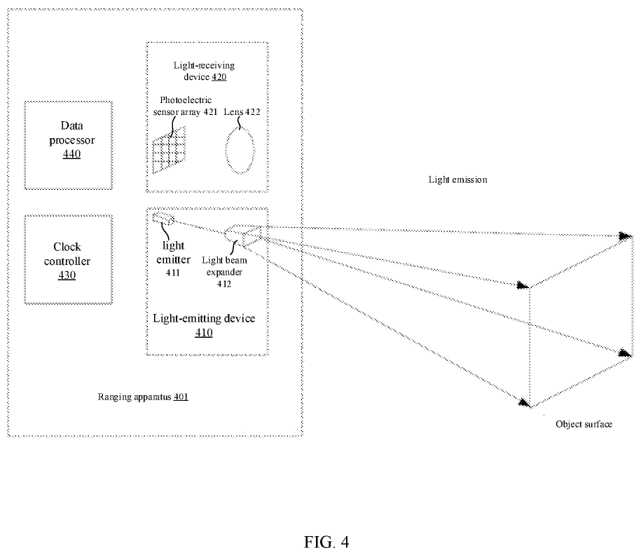

The present disclosure also provides a ranging apparatus. As shown in FIG. 4, in one embodiment, a ranging apparatus 401 includes a light-emitting device 410 and a light-receiving device 420. The light-emitting device 410 includes at least one laser diode package for emitting light signals. The light emitted by the light-emitting device 410 covers a field of view (FOV) of the ranging apparatus 401. The light-receiving device 420 is configured to receive light reflected by an object to be detected after the light is emitted by the light-emitting device 410, and calculate a distance between the ranging apparatus 401 and the object to be detected. The object to be detected is also referred to as a “target object.”

Each laser chip package of the at least one laser chip package may include: a base plate having a first surface; a cover provided at the first surface of the base plate where a receiving space is formed between the base plate and the cover; and laser diodes provided by various embodiments of the present disclosure in the receiving space for emitting laser pulse sequences. The base plate may be configured to be attached to a circuit board to electrically connect the laser diodes and the circuit board.

In one embodiment, the first surface of the substrate may face the first surface of the base plate.

In one embodiment, a transition plate may be disposed between the substrate and the base plate for buffering thermal expansion.

In one embodiment, the base plate may be a printed circuit board (PCB) base plate or a ceramic base plate.

In one embodiment, a distance between the light emitting regions of the adjacent laser diodes may be configured to satisfy a preset distance.

In one embodiment, at least a portion of different laser diodes in the laser diode package is configured to emit laser pulse sequences at different time.

The light-receiving device 420 may include at least two photoelectric converters. Each of the at least two photoelectric converters may correspond to a corresponding laser diode chip of the at least two laser diode chips in the light-emitting device 410. Each of the at least two photoelectric converters may be configured to receive at least a portion of the light in the laser pulse sequences from the corresponding laser diode chip reflected by an object, and convert the portion of the light to electric signals.

As shown in FIG. 4, the light-emitting device 410 includes a light emitter 411 and a light beam expander 412. The light emitter 411 is used to emit light, and the light beam expander 412 is used to perform at least one of collimation, beam expansion, homogenization, or field of view expansion on the light emitted by the light emitter 411. At least one of the collimation, beam expansion, homogenization, or field of view expansion may be performed on the light emitted by the light emitter 411 by the light beam expander 412, such that the emitted light becomes divergent and evenly distributed, which can cover a certain two-dimensional field in the scene. As shown in FIG. 4, the emitted light can cover at least part of the surface of the object to be detected.

In one embodiment, the light emitter 411 may include laser diodes. Optionally, the light emitter 411 may be a laser emitting device for emitting laser pulse sequences. The light emitter 411 may include the above-described laser diode package and a circuit board. The base plate in the laser diode package may be attached to the circuit board, such that the laser diodes in the laser diode package are electrically connected to the circuit board. In some embodiments, the distance between the light-emitting regions of different laser diodes in the laser emitting device may satisfy a preset distance, such that each light-emitting region may correspond to one photoelectric converter of the at least two photoelectric converters in a one-to-one correspondence.

In one embodiment, the light emitted by the light emitter 411 may have a wavelength between about 895 nanometers and about 915 nanometers. For example, light with a wavelength of 905 nanometers can be selected. In another embodiment, light with a wavelength between 1540 nanometers and 1560 nanometers can be selected. For example, light with a wavelength of 1550 nanometers can be selected. In various embodiments, light with other suitable wavelengths can also be selected according to application scenarios and various needs.

In one embodiment, the light beam expander 412 may be implemented by a one-stage or multi-stage beam expansion system. The light beam expansion processing can be reflective or transmissive, or a combination of the two. In one embodiment, a holographic filter may be used to obtain a large-angle beam including multiple sub-beams.

In another embodiment, a laser diode array, such as a vertical-cavity surface-emitting laser (VCSEL) array, may be adopted to form a plurality of light beams, which may realize an effect similar to beam expansion.

In another embodiment, a micro-electromechanical system (MEMS) micro mirror having adjustable two-dimensional angle can be used to reflect the emitted light. The MEMS micro mirror can be driven to constantly change the angle between the mirror surface and the beam, such that the angle of the reflected light may be constantly changed, thereby forming a two-dimensional diverse angle to cover the entire surface of the object to be detected.

The ranging apparatus may be used to sense external environment information, such as distance information, angle information, reflection intensity information, speed information, etc. of environmental targets. Specifically, the ranging apparatus of the present disclosure can be applied to a mobile platform, and can be installed on a platform body of the mobile platform. The mobile platform with the ranging apparatus can measure the external environment, for example, measuring the distance between the mobile platform and obstacles for obstacle avoidance and other purposes, or for two-dimensional or three-dimensional surveying and mapping of the external environment. In some embodiments, the mobile platform may include at least one of an unmanned aerial vehicle, a car, or a remote control car. When the ranging apparatus is applied to an unmanned aerial vehicle, the platform body can be a fuselage of the unmanned aerial vehicle. When the ranging apparatus is applied to a car, the platform body can be a body of the car. When the ranging apparatus is applied to a remote control car, the platform body may be a body of the remote control car.

The light emitted by the light-emitting device 410 may cover at least a portion of the surface or the whole surface of the object to be detected. Correspondingly, the light may be reflected after arriving at the surface of the object to be detected. The reflected light arrived at the light-receiving device 420 may be not a single point but be distributed in an array.

The light-receiving device 420 may include a photoelectric sensor array 421 and a lens 422. The light reflected at the surface of the object to be detected may arrive at the lens 422, and then may reach a corresponding photoelectric sensor in the photoelectric sensor array 421 based on the principle of lens imaging. Correspondingly, the light may be received by the corresponding photoelectric sensor, causing photoelectric response in photoelectric sensor.

Since during a process between light emission and the photoelectric sensor receiving the reflected light, the light emitter 411 and the photoelectric sensor array 421 may be controlled by a clock controller (for example, the clock controller 430 shown in FIG. 4 included in the ranging apparatus 401, or a clock controller external to the ranging apparatus 401), in synchronous clock control. Correspondingly, according to the time of flight (TOF) principle, the distance between the point reached by the reflected light and the ranging apparatus 401 be obtained.

The data processor 440 may be configured to determine the distance between the object reflecting the light corresponding to the electrical signal and the ranging apparatus 401, according to the electrical signal output by each photoelectric converter. In addition, since the ranging apparatus 401 includes the photoelectric sensor array 421 instead of a single point photoelectric sensor, the distance information of all points in the entire field of view of the ranging apparatus 401, that is, the point cloud data of the distance from the external environment that the ranging apparatus 401 faces, may be obtained, through data processing by the data processor 440 (such as the data processor 440 shown in FIG. 4 included in the ranging apparatus 401 or a data processor 440 external to the ranging apparatus 401).

Based on the foregoing structure and working principle of the laser diode package according to the embodiments of the present disclosure and the structure and working principle of the ranging apparatus according to the embodiments of the present disclosure, those skilled in the art can understand the structure and working principle of the electronic device according to the embodiments of the present disclosure.

The present disclosure also provides another ranging apparatus. The laser diode chips provided by various embodiments of the present disclosure may be applied to the ranging apparatus. The ranging apparatus may be an electronic device such as a lidar, or a laser ranging apparatus. In one embodiment, the ranging apparatus may be used to sense external environmental information, such as distance information, orientation information, reflection intensity information, speed information, etc. of environmental targets. In one embodiment, the ranging apparatus may detect the distance from the object to be detected to ranging apparatus by measuring time of light propagation, that is, time-of-flight (TOF), between the ranging apparatus and an object to be detected. In some other embodiments, the ranging apparatus may also detect the distance from the object to be detected to the ranging apparatus through other technologies, such as a ranging method based on phase shift measurement or a ranging method based on frequency shift measurement. The present disclosure has no limit on this.

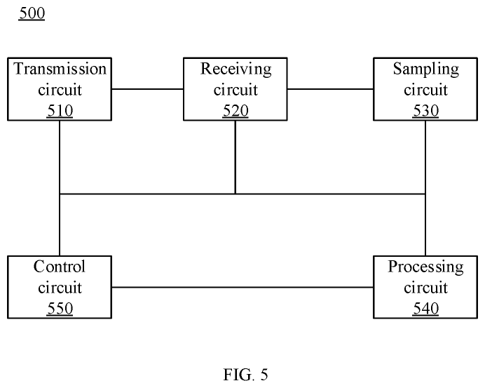

FIG. 5 is a schematic block diagram of an exemplary ranging apparatus 500 provided by some embodiments of the present disclosure.

As shown in FIG. 5, the ranging apparatus 500 includes a transmission circuit 510, a receiving circuit 520, a sampling circuit 530 and a processing circuit 540.

The transmission circuit 510 may emit a light pulse sequence (for example, a laser pulse sequence). The receiving circuit 520 may receive the light pulse sequence reflected by the object to be detected, and perform photoelectric conversion on the light pulse sequence to obtain an electrical signal. After processing the electrical signal, the electrical signal may be output to the sampling circuit 530. The sampling circuit 530 may sample the electrical signal to obtain a sampling result. The processing circuit 540 may determine the distance between the ranging apparatus 500 and the object to be detected based on the sampling result of the sampling circuit 530.

Optionally, in one embodiment, the ranging apparatus 500 further includes a control circuit 550 configured to achieve control on other circuits. For example, the control circuit 550 may be configured to control operation time of each circuit or configure parameters of each circuit.

For description purposes only, the embodiment in FIG. 5 where the ranging apparatus includes one transmission circuit, one receiving circuit, one sampling circuit, and one processing circuit, is used as an example to illustrate the present disclosure, and does not limit the scope of the present disclosure. In some other embodiments, the ranging apparatus may include at least two transmission circuits, or at least two receiving circuits, or at least two sampling circuits, or at least two processing circuits.

In some embodiments, the ranging apparatus 500 may further include a scanner configured to change the propagation direction of the laser pulse sequence from the transmission circuit to emit.

A module including the transmission circuit 510, the receiving circuit 520, the sampling circuit 530, and the processing circuit 540, or a module including the transmission circuit 510, the receiving circuit 520, the sampling circuit 530, the processing circuit 540, and the control circuit 550, may be denoted as a ranging module. The ranging module may be independent from other modules such as the scanner.

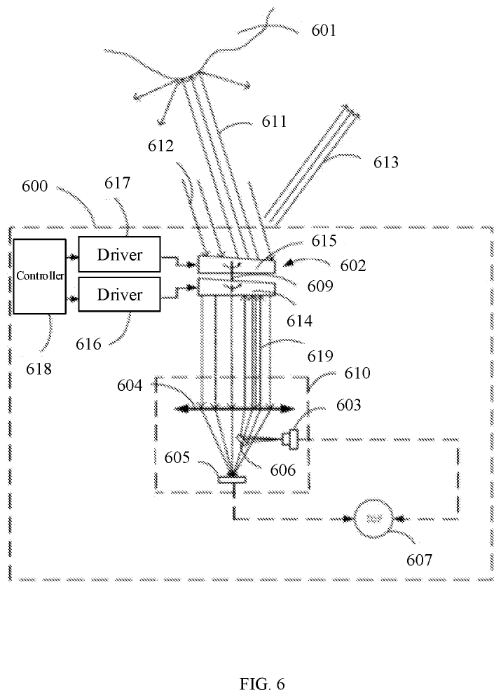

In one embodiment, the ranging apparatus may adopt a coaxial optical path, that is, the light beam emitted by the ranging apparatus and the reflected light beam may share at least part of the optical path in the ranging apparatus. Alternatively, in another embodiment, the ranging apparatus may adopt an off-axis optical path, that is, the light beam emitted by the ranging apparatus and the reflected light beam may be respectively transmitted along different optical paths in the ranging apparatus. FIG. 6 shows a schematic diagram of a ranging apparatus 600 adopting a coaxial optical path, provided by one embodiment of the present disclosure.

As shown in FIG. 6, the ranging apparatus 600 includes a light transceiver 610. The light transceiver 610 includes a light source 603 (including, e.g., the above-described transmission circuit), a collimator 604, a detector 605 (which may include the above-described receiving circuit, sampling circuit, or processing circuit), and an optical path adjustor 606. The light transceiver 610 may be used to transmit light beams, receive return light, and convert the return light into electrical signals. The light source 603 may be used to emit a light beam. In one embodiment, the light source 603 may emit a laser beam. Optionally, the laser beam emitted by the light source 603 may be a narrow-bandwidth beam with a wavelength outside the visible light range. The collimator 604 may be disposed at the emitting light path of the light source, and used to collimate the light beam emitted from the light source 603 into parallel light. The collimator may be also used to converge at least a part of the return light reflected by the object to be detected. The collimator 604 may be a collimating lens or another element capable of collimating light beams.

In the embodiment shown in FIG. 6, the optical path adjustor 606 may combine the transmission light path and the receiving light path in the ranging apparatus before the collimator 604, such that the transmission light path and the receiving light path can share the same collimator, making the optical path more compact. In some other embodiments, the light source 603 and the detector 605 may use their respective collimators, and the optical path adjustor 606 may be disposed behind the collimator.

In the embodiment shown in FIG. 6, since the beam divergence angle of the light beam emitted by the light source 603 is small, and the beam divergence angle of the return light received by the ranging apparatus is large, the optical path adjustor may use a small area reflective mirror to combine the transmission light path and the receiving light path. In some other embodiments, the optical path adjustor may adopt a reflective mirror with a through hole. The through hole may be used to transmit the emitted light of the light source 603 and the reflective mirror may be used to reflect the return light to the detector 605. Correspondingly, when a small reflective mirror is used, it is possible to reduce the blocking of the return light by the support of the small reflective mirror.

In the embodiment shown in FIG. 6, the optical path adjustor deviates from the optical axis of the collimator 604. In some other embodiments, the optical path adjustor may also be located on the optical axis of the collimator 604.

The ranging apparatus 600 further includes a scanner 602. The scanner 602 is placed on the exit light path of the light transceiver 610. The scanner 602 may be used to change the transmission direction of the collimated beam 619 emitted by the collimator 604 and project it to the external environment, and project the return light to the collimator 604. The returned light may be collected on the detector 605 via the collimator 604.

In one embodiment, the scanner 602 may include one or more optical elements, such as, a lens, a mirror, a prism, a grating, an optical phased array, or any combination thereof. In some embodiments, the one or more optical elements of the scanner 602 may rotate around a common axis 609, and each of the one or more optical elements may rotate to continuously change the propagation direction of the incident light beam. In one embodiment, the one or more optical elements of the scanner 602 may rotate at different rotation speeds. In another embodiment, the one or more optical elements of the scanner 602 may rotate at substantially the same rotation speed.

In some embodiments, one or more optical elements of the scanner may rotate around different axes. In some other embodiments, the one or more optical elements of the scanner may rotate in the same direction or in different directions; or vibrate in the same direction, or vibrate in different directions, which is not limited herein.

In one embodiment, the scanner 602 includes a first optical element 614 and a driver 616 connected to the first optical element 614. The driver 616 is used to drive the first optical element 614 to rotate around a rotation axis 609, such that the first optical element 614 changes the direction of the collimated beam 619. The first optical element 614 projects the collimated beam 619 to different directions. In one embodiment, the angle between the direction of the collimated beam 619 after being changed by the first optical element and the rotation axis 609 may change with the rotation of the first optical element 614. In one embodiment, the first optical element 614 may include a pair of opposed non-parallel surfaces through which the collimated light beam 619 can pass. In another embodiment, the first optical element 614 may include a prism whose thickness varies in at least one radial direction. In another embodiment, the first optical element 614 may include a wedge prism configured to refract the collimated beam 619. In one embodiment, the first optical element 614 may be coated with an anti-reflection coating, and the thickness of the anti-reflection coating may be equal to the wavelength of the light beam emitted by the light source 603, which can increase the intensity of the transmitted light beam.

In one embodiment, the scanner 602 further includes a second optical element 615, and the second optical element 615 may rotate around the rotation axis 609. A rotation speed of the second optical element 615 may be different from a rotation speed of the first optical element 614. The second optical element 615 may be used to change the direction of the light beam projected by the first optical element 614. In one embodiment, the second optical element 615 may be connected to another driver 617, and the driver 617 may drive the second optical element 615 to rotate. The first optical element 614 and the second optical element 615 may be driven by different drivers, such that the rotation speeds of the first optical element 614 and the second optical element 615 are different. Correspondingly, the collimated beam 619 may be projected to different directions in the external space, which can scan a larger space range. In one embodiment, a controller 618 may be configured to control the driver 616 and the driver 617 to drive the first optical element 614 and the second optical element 615, respectively. The rotational speeds of the first optical element 614 and the second optical element 615 can be determined according to the expected scanning area and pattern in actual applications. The drivers 616 and 617 may include motors or other driving devices.

In one embodiment, the second optical element 615 may include a pair of opposite non-parallel surfaces through which the light beam can pass. In another embodiment, the second optical element 615 may include a prism whose thickness varies along at least one radial direction. In another embodiment, the second optical element 615 may include a wedge prism. In one embodiment, the second optical element 615 may be coated with an anti-reflection coating, which can increase the intensity of the transmitted light beam.

The scanner 602 may rotate to project light to different directions, such as a direction 611 and a direction 613, such that the space around the ranging apparatus 600 is scanned. When the light 611 projected by the scanner 602 hits the object to be detected 601, a part of the light may be reflected by the object to be detected 601 to ranging apparatus 600 in a direction opposite to the projected light 611. The scanner 602 may receive the return light 612 reflected by the object to be detected 601 and projects the return light 612 to the collimator 604.

The collimator 604 may converge at least a part of the return light 612 reflected by the object to be detected 601. In one embodiment, an anti-reflection coating may be plated on the collimator 604, to increase the intensity of the transmitted light beam. The detector 605 and the light source 603 may be placed on the same side of the collimator 604, and the detector 605 may be used to convert at least part of the return light passing through the collimator 604 into an electrical signal.

In some embodiments, the light source 603 may include a laser diode through which nanosecond laser light is emitted. For example, the laser pulse emitted by the light source 603 may last for 10 ns. Further, the laser pulse receiving time can be determined, for example, the laser pulse receiving time can be determined by detecting the rising edge time and/or the falling edge time of the electrical signal pulse. Correspondingly, ranging apparatus 600 can calculate the TOF by using the pulse receiving time information and the pulse sending time information, to determine the distance between the object to be detected 601 and ranging apparatus 600.

The distance and orientation detected by ranging apparatus 600 can be used for remote sensing, obstacle avoidance, surveying and mapping, modeling, navigation, and the like.

In one embodiment, the ranging apparatus may be applied to a mobile platform, and the ranging apparatus may be installed on a platform body of the mobile platform. The mobile platform with the ranging apparatus may measure the external environment, for example, measuring the distance between the mobile platform and obstacles for obstacle avoidance or other purposes, or for two-dimensional or three-dimensional mapping of the external environment. In some embodiments, the mobile platform may include at least one of an unmanned aerial vehicle, a car, a remote control car, a robot, or a camera. When the ranging apparatus is applied to an unmanned aerial vehicle, the platform body may be a fuselage of the unmanned aerial vehicle. When the ranging apparatus is applied to a car, the platform body may be a body of the car. The car may be a self-driving car or a semi-self-driving car, and there is no limit here. When the ranging apparatus is applied to a remote control car, the platform body may be a body of the remote control car. When the ranging apparatus is applied to a robot, the platform body may be the robot. When the ranging apparatus is applied to a camera, the platform body may be the camera itself.

Although exemplary embodiments have been described herein with reference to accompanying drawings, it should be understood that the above-described exemplary embodiments are merely examples, and are not intended to limit the scope of the present disclosure. Those of ordinary skill in the art can make various changes and modifications thereto without departing from the scope and spirit of the present disclosure. All these changes and modifications are intended to be included in the scope of the present disclosure.

A person of ordinary skill in the art may realize that the units and algorithm steps of the examples described in combination with the embodiments disclosed herein can be implemented by electronic hardware or a combination of computer software and electronic hardware. Whether these functions are executed by hardware or software depends on the specific application and design constraint conditions of the technical solution. Professionals and technicians can use different methods for each specific application to implement the described functions, but such implementation should not be considered as going beyond the scope of the present disclosure.

In the several embodiments provided in this application, it should be understood that the disclosed device and method may be implemented in other manners. For example, the device embodiments described above are only illustrative. For example, the division of the units may be only a logical function division, and there may be other divisions in actual implementation, e.g., multiple units or components can be combined or can be integrated into another device, or some features can be omitted or not implemented.

In the disclosure, a lot of specific details are explained. However, it can be understood that the embodiments of the disclosure can be practiced without these specific details.

Similarly, it should be understood that, in order to simplify the description of the present disclosure and help to understand one or more of the various aspects of the disclosure, in the description of the exemplary embodiments of the disclosure, the various features of the disclosure are sometimes grouped together into a single embodiment, figure, or the description thereof. However, the disclosure should not be interpreted to mean that the claimed invention requires more features than those explicitly recited in each claim. More precisely, as reflected in the corresponding claims, the invention can solve corresponding technical problems with features that are less than all the features of a single disclosed embodiment. Therefore, the claims following the specific embodiment are thus explicitly incorporated into the specific embodiment, where each claim itself serves as a separate embodiment of the present disclosure.

Those skilled in the art can understand that, unless there is a conflict, any combination of any features disclosed in this specification (including the accompanying claims, abstract, and drawings) and any processes or units of the method or device so disclosed can be allowed. Unless expressly stated otherwise, each feature disclosed in this specification (including the accompanying claims, abstract, and drawings) may be replaced by an alternative feature providing the same, equivalent, or similar purpose.

In addition, those skilled in the art can understand that although some embodiments described herein include certain features of other embodiments but not some other features, the combination of features of different embodiments is still within the scope of the disclosure and constitute an embodiment of the disclosure. For example, in the claims, any one of the claimed embodiments can be used in any combination.

The various component embodiments of the present disclosure may be implemented by hardware, or by software modules running on one or more processors, or by a combination of them. Those skilled in the art should understand that a microprocessor or a digital signal processor (DSP) may be used in practice to implement some or all of the functions of some modules according to the embodiments of the disclosure. An embodiment of the disclosure can also be implemented as a device program (for example, a computer program and a computer program product) for executing part or all of the methods described herein. Such a program for realizing the disclosure may be stored on a computer-readable medium, or may have the form of one or more signals. Such a signal can be downloaded from an Internet website, or provided on a carrier signal, or provided in any other form.

It should be noted that the above-described embodiments illustrate rather than limit the disclosure, and those skilled in the art can design alternative embodiments without departing from the scope of the disclosure. The disclosure can be implemented by means of hardware including several different elements or by a suitably programmed computer. In an embodiment having several devices, some or all of these devices may be embodied in a same hardware item. The use of the words “first,” “second,” and “third,” etc. does not indicate any order. These words can be interpreted as names.

The above are only specific implementations or descriptions of specific implementations of the disclosure. The scope of the disclosure is not limited thereto. Any change or replacement conceived by a person skilled in the art that falls within the technical scope disclosed by the disclosure should be included in the scope of the disclosure. The protection scope of the present invention shall be subject to the appended claims.

What is claimed is:

1. A laser diode chip comprising:
a substrate including a first surface and a second surface; and
a laser diode array including at least two laser diodes formed at the substrate and each including:
a P electrode formed at the first surface of the substrate;
an N electrode formed at the second surface of the substrate; and
a light emitting region formed between the P electrode and N electrode;
wherein adjacent N electrodes of adjacent laser diodes of the at least two laser diodes are isolated from each other.

2. The laser diode chip according to claim 1, further comprising:
an isolation channel between the adjacent N electrodes.

3. The laser diode chip according to claim 2, wherein:
the isolation channel includes a groove formed between the adjacent N electrodes by etching or cutting.

4. The laser diode chip according to claim 3, wherein:
the groove is filled with an insulation material.

5. The laser diode chip according to claim 2, wherein:
a size of the isolation channel along a thickness direction of the substrate is larger than or equal to a size of one of the adjacent N electrodes along the thickness direction of the substrate, and is smaller than a thickness of the substrate.

6. The laser diode chip according to claim 2, wherein:
the N electrodes of the at least two laser diodes are formed by cutting a common N electrode formed at the second surface of the substrate.

7. The laser diode chip according to claim 6, wherein a size of the N electrode along a length direction the substrate is larger than a size of the P electrode along a length direction the substrate.

8. The laser diode chip according to claim 1, wherein the P electrodes of the adjacent laser diodes are isolated by an intrinsic region or a lightly doped region at the first surface of the substrate.

9. The laser diode chip according to claim 1, wherein:
the substrate includes an intrinsic semiconductor substrate or an N-type semiconductor substrate.

10. The laser diode chip according to claim 1, wherein:
the adjacent N electrodes are isolated by an intrinsic region or a lightly doped region at the first surface of the substrate.

11. The laser diode chip according to claim 10, wherein:
the at least two laser diodes share a P electrode formed at the first surface of the substrate.

12. The laser diode chip according to claim 10, wherein:
the substrate includes an intrinsic semiconductor substrate or a P-type semiconductor substrate.

13. A laser diode package comprising:
a base plate including a surface;
a cover disposed at the surface of the base plate, an accommodation space being formed between the cover and the base plate; and
a laser diode chip arranged in the accommodation space and including:
a substrate including a first surface and a second surface; and
a laser diode array including at least two laser diodes formed at the substrate and each including:
a P electrode formed at the first surface of the substrate;
an N electrode formed at the second surface of the substrate; and
a light emitting region formed between the P electrode and N electrode;
wherein adjacent N electrodes of adjacent laser diodes of the at least two laser diodes are isolated from each other.

14. The laser diode package according to claim 13, wherein the first surface of the substrate faces the surface of the base plate.

15. The laser diode package according to claim 13, further comprising:
a transition plate between the substrate and the base plate.

16. The laser diode package according to claim 13, wherein:
the base plate includes a printed circuit board (PCB) base plate or a ceramic base plate.

17. The laser diode package according to claim 13, wherein a distance between the adjacent laser diodes satisfies a preset distance.

18. The laser diode package according to claim 13, wherein:
at least some of the at least two laser diodes are configured to emit laser pulse sequences at different times.

19. A laser transmission apparatus comprising:
the laser diode package of claim 13; and
a circuit board;
wherein the base plate is attached to the circuit board and electrically couples the laser diode chip to the circuit board.

20. A ranging apparatus comprising:
a circuit board;
a base plate attached to the circuit board and including a surface;
a cover disposed at the surface of the base plate, an accommodation space being formed between the cover and the base plate;
a laser diode chip arranged in the accommodation space and electrically coupled to the circuit board via the base plate, the laser diode chip including:
a substrate including a first surface and a second surface; and
a laser diode array including at least two laser diodes formed at the substrate and each including:
a P electrode formed at the first surface of the substrate;
an N electrode formed at the second surface of the substrate; and
a light emitting region formed between the P electrode and N electrode;
wherein adjacent N electrodes of adjacent laser diodes of the at least two laser diodes are isolated from each other;
at least two photoelectric converters corresponding to the at least two laser diodes in a one-to-one correspondence, each of the at least two photoelectric converters being configured to:
receive at least part of a light beam emitted by a corresponding one of the at least two laser diodes and reflected by an object, and
convert the at least part of the light beam to an electric signal; and
a data processor configured to determine a distance between the object and the ranging apparatus based on the electric signal.
